(19) United States
(12) Patent Application Publication
(10) Pub. No.: US 2002/0167630 A1
(43) Pub. Date: Nov. 14, 2002

(54) Display apparatus

(75) Inventors: Ichiro Fujieda, Tokyo (JP); Takashi Fukuchi, Tokyo (JP); Masayoshi Suzuki, Tokyo (JP)

Correspondence Address: Paul J. Esatto, Jr., Scully, Scott, Murphy & Presser, 400 Garden City Plaza, Garden City, NY, 11530, US

(73) Assignee: NEC Corporation, Tokyo (JP)

(21) Appl. No.: 10/095,197

(22) Filed: Mar. 11, 2002

(30) Foreign Application Priority Data
Mar. 13, 2001 (JP) 2001-071184

(51) Int. Cl. G02F 1/1335

(52) U.S. Cl. 349/117

(57) ABSTRACT

Light emitting means has a configuration such that an optically active medium having a spiral structure, a quarter-wave plate, and a linear polarization plate are provided over light emitting elements formed by stacking a mirror-reflecting electrode, an organic EL layer, and a transparent electrode.

### BACKGROUND OF THE INVENTION

1. Field of the Invention

The present invention relates to a flat-panel display apparatus used for a device such as a portable information terminal, portable telephone, personal computer, or television and, more particularly, to a display using a light guiding element having characteristics such as thinness, lightness, and low manufacturing cost.

The invention also relates to a display using a light guiding element, which is housed in a small casing when unused.

2. Related Background Art

Conventionally, a display such as a liquid crystal display (LCD) is being practically used as a display of a device such as a portable information terminal, game device, portable telephone, personal computer, or television.

Particularly, a thin film transistor (TFT) LCD having a configuration of driving each of liquid crystal cells by using TFTs provided for pixels has advantages such that an image can be displayed with high definition and fast response, so that its use is being widened.

However, the process of manufacturing a liquid crystal cell including a TFT is complicated. In particular, the larger the display area becomes, the higher the manufacturing cost becomes. By the performances of a sputtering device, CVD device, exposure equipment, and the like for manufacturing a TFT, the display area which can be manufactured is limited.

To solve such problems, a display constructed by a one-dimensional light emitting element array, a light guiding element array, or the like has been proposed by the inventor herein.

Such a conventional display using a light guiding element will be described first with reference to FIGS. 13 and 14.

FIG. 13 is an exploded perspective view showing main components of a conventional display.

The display is constructed by, as shown in FIG. 13, light emitting means 110 having a plurality of light emitting elements 111, light guiding means 120 in which a plurality of light guiding elements 121 are arranged on a supporting substrate 122, light extracting means 130 constructed by sealing a liquid crystal layer 131 with a transparent substrate 133 on which a plurality of electrodes 134 are formed and a liquid crystal sealing material 132, and light reflecting means 140.

The optical axes 112 of the light emitting elements 111 are arranged so that light enters from ends of the light guiding elements 121, and the light reflecting means 140 is disposed so as to reflect light which reaches the other end of the light guiding elements 121.

The electrodes 134 are formed on the face of the transparent substrate 133, which is in contact with the liquid crystal layer 131, and terminal groups 138 for connection to the outside are provided in two peripheral portions of the transparent substrate 133 as shown in FIG. 13.

Referring now to FIGS. 14a and 14b, the operations of the light guiding means 120 and the light extracting means 130 will be described.

Light emitted from each of the light emitting elements 111 of the light emitting means 110 enters the light guiding element 121 disposed so as to face the light emitting element 111 and propagates through a high refractive index area 121a of the light guiding element 121.

As shown in FIG. 14a, when a potential difference is not given between electrodes 134a and 134b, liquid crystal molecules are aligned in the direction almost horizontal to the substrate, and the refractive index of the liquid crystal layer 131 for light traveling through the high refractive index area 121a is lower than that of the high refractive index area 121a.

Therefore, light remains in the high refractive index area 121a and is not leaked to the liquid crystal layer 131. As shown in FIG. 14b, when an electric field is generated by the potential difference between the electrodes 134a and 134b, the liquid crystal molecules are oriented as shown in the drawing and the refractive index increases.

The condition for the total internal reflection at the interface between the liquid crystal layer 131 and the high refractive index area 121a is broken. Light leaks from the high refractive index area 121a, and the leaked light propagates through the liquid crystal layer 131. It enters a light scattering layer 136 at an acute angle.

After the light is diffused by the light scattering layer 136, the light sequentially passes through the transparent substrate 133 and an antireflection film 137 and reaches the observer (user). In FIGS. 14a and 14b, a numeral 135 designates an alignment layer for the liquid crystal layer.

The operation of displaying an image is performed as follows. First, light in a pattern corresponding to the first line of an image to be displayed is emitted from the light emitting means 110 and enters and propagates the light guiding element 121 corresponding to each light emitting element. Simultaneously, control signals are supplied to the electrodes 134a and 134b positioned in the first column of the display area in order to change the orientations of the liquid crystal molecules in the corresponding region.

In such a manner, light output from the light emitting means 110 is obtained only from the first line of the display area. By repeating the operation with respect to all of the lines, an arbitrary image can be displayed. Only from one line in the display area, light leaks at any moment during the displaying operation. As in the case of a CRT, a laser display, or the like, due to an after-image phenomenon, an image is formed in the observer's brain.

To display colored images, it is sufficient to use light emitting means which outputs three primary colors of R (red), G (green), and B (blue). Examples of such light emitting means include light emitting means obtained by combining color filters and a white light emitting material, light emitting means obtained by combining a blue light emitting material and a color converting material, and light emitting means obtained by disposing light emitting materials of three colors in parallel or the like.

The conventional displays each using the light guiding element described above have the following problems.

First, in FIG. 14, with respect to a polarization component, electric field of which vibrates in the direction parallel to the drawing sheet, as described above, light can be allowed to leak to the outside of the light guiding element by controlling the orientation of the liquid crystal molecules.

However, with respect to a polarization component, electric field of which vibrates in the direction perpendicular to the drawing sheet, since the refractive index of the liquid crystal layer 131 is always fixed irrespective of the orientation state, light cannot be made leak to the outside of the light guiding element. The light confined in the light guiding element is lost due to a phenomenon of scattering caused by irregularity of the surface shape of the light guiding element or the like.

It consequently means that the half of the light cannot be used for display.

In order to employ such a display for use in which low power consumption is important like devices such as a portable information terminal and a notebook-sized PC, a configuration capable of using light in both of the above-described polarized states, that is, polarization having the electric field component parallel to the drawing sheet and polarization having the electric field perpendicular to the drawing sheet is desired.

Second, to make light propagate through the light guiding element, light has to enter the light guiding element at an angle smaller than a certain angle. Therefore, in the case in which the directivity of the light emitting element is wide (not narrow), the number of photons which cannot propagate through the light guiding element increases as the distance between the light emitting element and the end of the light guiding element increases. That is, the ratio of light which cannot be used for display purpose increases, the efficiency for light utilization deteriorates, and it becomes more disadvantageous for the use in which the low power consumption is important.

Third, in the case of using light emitting devices which output three primary colors of R, G, and B to realize a color display, at least one of the above-described configurations of the light emitting means such as combination of color filters and a white light emitting material can be used. However, the manufacturing cost of any of the light emitting means is high. It is therefore desired to reduce the manufacturing cost by decreasing the number of parts.

### SUMMARY OF THE INVENTION

The present invention has been achieved in consideration of the above circumstances and its object is to provide a display having high efficiency for light utilization, which can be driven with low power consumption and realized at low cost.

To obtain the above object, the present invention basically adopts the following technique constitution.

The first aspect of the present invention is a display apparatus comprising: a plurality of light guiding means; a light emitting means, an emitting light of which includes a first polarization component and a second polarization component which is different from the first polarization component, that emits the light so as to enter the plurality of light guiding means; a liquid crystal layer, provided on the plurality of light guiding means, for making the light from the plurality of light guiding means leak to an outside; and a polarization recycling means, provided between the light emitting means and the plurality of light guiding means, for converting the second polarization component into the first polarization component.

In the second aspect of the present invention, the polarization converting means is formed by stacking a cholesteric liquid crystal polymer, a quarter-wave plate and a linear polarization plate.

In the third aspect of the present invention, the light emitting means comprising a bottom electrode made of a reflecting material formed on a substrate and a top electrode made of a transparent material and an organic electroluminescence layer provided between the bottom electrode and the top electrode.

In the fourth aspect of the present invention, the light emitting means is an edge emitting type light emitting element.

In the fifth aspect of the present invention, the light emitting means outputs white light and color filters are disposed over the liquid crystal layer.

In the sixth aspect of the present invention, the color filter includes a component for scattering a light which is extracted via the liquid crystal layer.

In the seventh aspect of the present invention, the light emitting means outputs white light and color filters are disposed between the light emitting means and the plurality of light guiding means.

### BRIEF DESCRIPTION OF THE DRAWINGS

FIG. 1 is an exploded perspective view showing the first embodiment of the present invention;

FIG. 2 is a sectional view showing the joint portion between light guiding means and light emitting means in FIG. 1;

FIG. 3 is an exploded perspective view showing a modification of the first embodiment of the present invention;

FIG. 4 is a sectional view showing the joint portion between light guiding means and light emitting means in FIG. 3;

FIG. 5 is an exploded perspective view showing the second embodiment of the present invention;

FIG. 6 is a sectional view showing the joint portion between light guiding means and light emitting means in FIG. 5;

FIG. 7 is a graph explaining the operation of the second embodiment of the display of the present invention;

FIG. 8 is another graph for explaining the operation of the second embodiment of the present invention;

FIG. 9 is another graph for explaining the operation of the second embodiment of the present invention;

FIG. 10 is another graph for explaining the operation of the second embodiment of the present invention;

FIG. 11 is an exploded perspective view showing a modification of the second embodiment of the present invention;

FIG. 12 is a sectional view showing the joint portion between light guiding means and light emitting means in FIG. 11;

FIG. 13 is an exploded perspective view showing a conventional display using light guiding elements; and

FIGS. 14a and 14b are drawings showing the principle of operation of the conventional display using the light guiding elements.

### DETAILED DESCRIPTION OF THE PREFERRED EMBODIMENTS

The invention will be described in detail hereinbelow by embodiments.

### FIRST EMBODIMENT

A first problem of the conventional technique is that since only light of one of the polarization components is used for display purpose, the efficiency for light utilization becomes (about) one half.

To solve the problem, a first embodiment is carried out on the basis of the above-mentioned motivation.

The configuration, an example of operation, materials used, a manufacturing method, an example of numerical values in designing, and the like will be sequentially described hereinbelow.

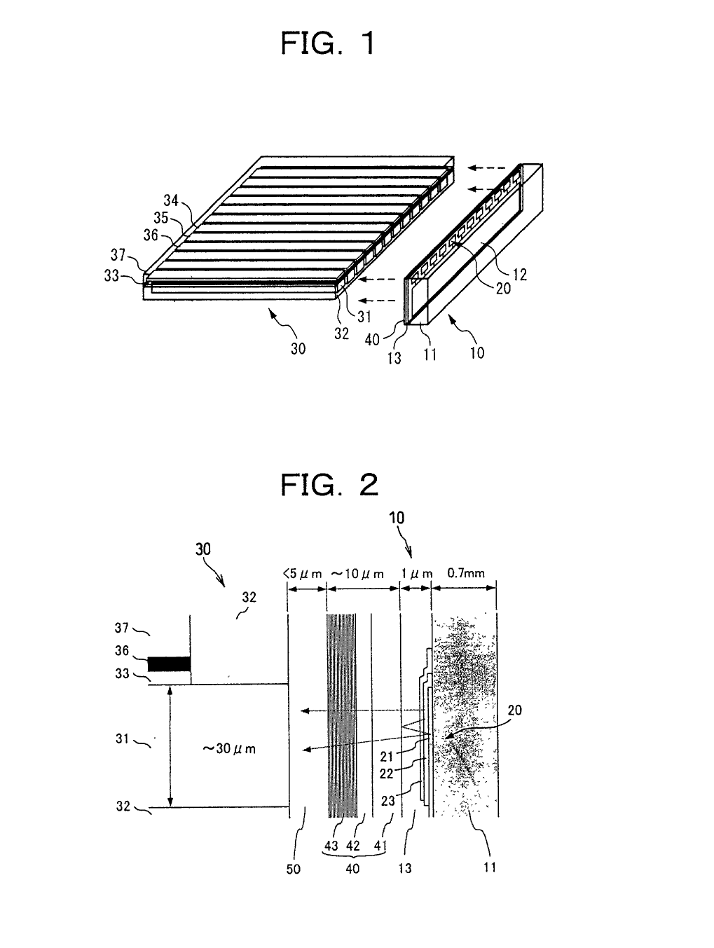

FIG. 1 is an exploded perspective view showing the configuration of light emitting means 10 and light guiding means 30 used for a display of the present invention.

The light emitting means 10 has a plurality of light emitting elements 20 arranged regularly on one of the surfaces of an insulating substrate 11 and a drive circuit 12 constructed by thin film transistors (TFTs) to drive the light emitting elements 20. On the surface of the light emitting means 10, a protective layer 13 is formed.

The protective layer 13 is provided to protect the light emitting elements 20 by preventing water and other materials such as impurities from entering the light emitting elements 20.

The light guiding means 30 has a plurality of cores 31 regularly arranged, a cladding 32 disposed closely attached to the bottom of the cores 31, and a light extracting portion 33 closely attached on the cores 31. The light extracting portion 33 includes a liquid crystal layer. Further, on the light extracting portion 33, color filters 34, 35, and 36 of three primary colors and a protective layer 37 are closely attached. The color filters 34, 35, and 36 of three colors are formed over the cores 31 via the light extracting portion 33.

FIG. 2 is a cross section of a joint portion between the light guiding means 30 and the light emitting means 10. The light emitting element 20 is formed by sequentially stacking a bottom (reflection) electrode 21, an organic EL layer 22, and a top (transparent) electrode 23 on one of the surfaces of the insulating substrate 11. Further, on the top (transparent) electrode 23, polarization recycling means 40 is disposed via the protective layer 13. The polarization recycling means 40 is formed by, as shown in FIG. 2, sequentially stacking a cholesteric liquid crystal polymer 41, a quarter-wave plate 42, and a linear polarization plate

The light emitting means 10 including the polarization recycling means 40 is fixed to the light guiding means 30 via an adhesive layer 50.

The operation of the embodiment will now be described with reference to FIGS. 1 and 2.

The light emitting element 20 includes the bottom electrode made of a reflecting material and the top electrode made of a transparent material. By applying a bias between the two electrodes, light is emitted through the transparent electrodes 23.

The wavelength of light emitted largely depends on the selection of an organic EL material. In the embodiment, a material which emits white light is used.

Light includes left circular polarization (circular polarization in the left direction) and right circular polarization (circular polarization in the right direction) One of the circular polarization (for convenience, left circular polarization in the following description) passes through the cholesteric liquid crystal polymer 41 (which has a right-turn spiral structure). On the other hand, the right circular polarization is selectively reflected by the cholesteric liquid crystal polymer 41. That is, the light reflected by the liquid crystal is only the right circular polarization. It is different from reflection such as reflection on a mirror where the both circular polarization components are reflected and the directions of turn are reversed.

The reflected right circular polarization sequentially passes through the protective layer 13, transparent electrode 23, and organic EL layer 22 and reaches the bottom electrode 21. Since the bottom electrode 21 acts as a mirror, the reflected light becomes the left circular polarization. When this light reaches the cholesteric liquid crystal polymer 41, it passes through the liquid crystal layer. The phenomenon of selective reflection by the cholesteric liquid crystal polymer layer depends on the wavelength. For example, in the case of using white light, the cholesteric liquid crystal polymer having a spiral pitch according to the wavelength at which light has to be transmitted is constructed as follows. That is, it has three layers (for example, by, stacking layers of the cholesteric liquid crystal having the spiral pitches of R, G, and B).

In the embodiment, by the combination of the cholesteric liquid crystal polymer 41 and the bottom electrode of the light emitting element 20, both the right and left circular polarization can be used. The left circular polarization passed through the cholesteric liquid crystal polymer 41 is converted to linearly polarized light by the quarter-wave plate 42 and passes through the linear polarization plate 43.

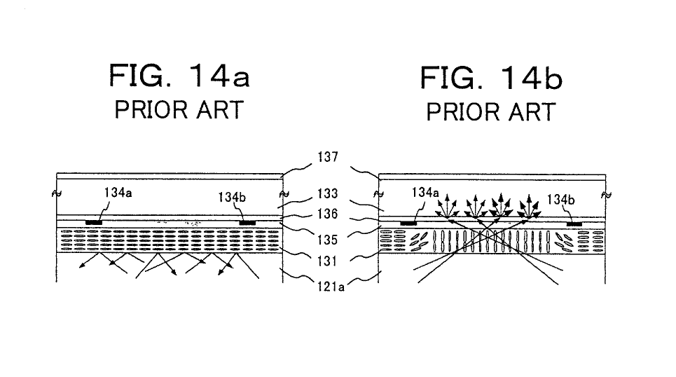

As described above, the light entering the cores 31 of the light guiding means 30 is linearly polarized in one direction and an image can be displayed by using this light. For example, in the case of the orientation of the liquid crystal shown in FIG. 14, the optical axis of the linear polarization plate 43 is adjusted so that the linearly polarized light in the direction parallel to the drawing sheet enters the cores 31. Desired linearly polarized light reaching the cores 31 is selectively extracted by the light extracting portion 33 and reaches the color filters 34, 35, and 36. Each color filter includes particles which diffuse light. Light of the selected color is emitted through the protective layer 37 on the color filter.

As described above, in the embodiment, light emitted from the light emitting means is converted to light in a desired polarization state and the resultant light is allowed to enter the light guiding means, thereby enabling light to be efficiently used and, as a result, the brightness of display can be increased by about twice. In other words, the power consumption to obtain the same brightness can be reduced to one half as compared with that of the conventional technique.

Since the color filter having the function of diffusing light is formed as a part of the light guiding means, the process of forming a light scattering layer separately needed in the conventional configuration is unnecessary. Consequently, the manufacturing process is shortened and the manufacturing cost can be reduced.

Concrete examples of the kinds of materials, dimensions, manufacturing methods, and the like of the elements used for the above-described configuration will be described.

First, the light emitting means 10 will be described.

### EXAMPLE OF FORMATION OF LIGHT EMITTING MEANS

The arrangement pitch of the light emitting elements 20 in the light emitting means 10 is set to 32 μm corresponding to the pixel pitch of a color display having the definition of 200 ppi (pixel per inch). As the insulating substrate 11, a substrate generally used in a TFT process such as a no-alkali glass substrate having a thickness of 0.7 mm is used. By a process using the polysilicon TFT technique, the drive circuit 12 is formed. With respect to the process and material, other various known methods can be also employed.

Subsequently, as a cathode of the light emitting element, a material such as an aluminum—lithium alloy is subjected to vacuum evaporation or the like via a shadow mask made of a metal, thereby forming the bottom electrode 21 having a thickness of about 200 nm.

On the bottom electrode 21, the organic EL layer 22 is formed. The organic EL layer 22 may employ a configuration such as a two-layered configuration of a light emitting layer and a hole injection and transport layer, a three-layered configuration in which an electron injection and transport layer is added to the two-layered configuration, a configuration in which a thin insulating film is provided on the interface between the bottom electrode 21 made of a metal and the organic EL layer 22, or the like.

In the example of the configuration shown in FIG. 2, the organic EL layer 22 is a single layer. However, the organic EL layer 22 may have any of the above layer configuration. The organic EL layer 22 can be manufactured by spin coating, vacuum evaporation, inkjet printing, or the like. According to the manufacturing method, a polymer organic EL material or a low molecular weight organic EL material can be selected. For example, at least one of triallyl amine derivative, an oxadiazole derivative, porphyrin derivative and the like can be selected as the material for the hole injection and transport layer. As a material for the light emitting layer, for example, at least one of 8-hydroxyquinoline, an 8-hydroxyquinoline derivative (particularly, metal complex of the derivative), a tetraphenylbutadiene derivative, a distrill allyl derivative, and the like can be selected. Each of those materials can be formed in a thickness of about 50 nm by, for example, vacuum evaporation.

Subsequently, a material such as an indium tin oxide (ITO) alloy or the like is deposited on the entire surface by sputtering to form the transparent electrode 23 serving as an anode. In the case of using ITO as the material of such an anode, the sheet resistance becomes about 20 Ω/□ and the film can be formed to a thickness of about 100 nm.

Finally, to protect these stacked layers from oxygen and moisture, a film is formed on the entire face by using a silicon oxide or a silicon nitride, thereby forming the protective layer 13. In such a manner, the light emitting means can be manufactured.

### EXAMPLE OF FORMATION OF POLARIZATION RECYCLING MEANS

An example for formation of the polarization recycling means 40 will now be described.

The polarization recycling means 40 is provided on the top surface of the light emitting means 10 as follows. The cholesteric liquid crystal polymer has a three-layer structure in which the pitch of spiral corresponds to three primary colors of red (R), green (G), and blue (B). At the time of stacking the three layers, it is also possible to gradually vary the spiral pitch of the liquid crystal so that the cholesteric liquid crystal polymer is adapted to the wavelengths of the entire visible range as a whole.

The layer in which the spiral pitch gradually changes can be formed by using materials and a method described by, for example, R. Mauer, D. Andrejewski, F-H. Kreuzer, and A. Miller, SID 90 DIGEST, pp. 110-112 (1990). We can adhere the polarization recycling means 40 formed as described above onto the top surface of the light emitting means 10. It is also possible to form the polarization recycling means 40 directly on the top surface of the light emitting means 10 by spin coating of the materials mentioned above or the like.

Conventional films used for each of the quarter-wave plate and the linear polarization plate may be directly adhered onto the top surface of the cholesteric liquid crystal polymer layer. It is also desirable to directly coat the top surface of the cholesteric liquid crystal polymer layer with a liquid material of each of the quarter-wave plate and the linear polarization plate by spin coating or the like. The film thickness in this case may be set to about the thickness shown in FIG. 2, and the film can be made sufficiently thinner than the core 31.

### EXAMPLE OF FORMATION OF LIGHT GUIDING MEANS

With respect to the light guiding means 30, the arrangement pitch of the cores 31 is set to 32 μm corresponding to the pixel pitch.

A method of manufacturing the cores 31 and the cladding 32 is as follows.

First, the whole surface of a supporting substrate, which is made of a polymer material having a thickness of 25 μm to 750 μm, is coated with a polymer material I such as photosensitive acrylic resin by spin coating or the like. Subsequently, by an exposing process and an etching process according to a photolithography method, the cores 31 arranged at the pitch of 32 μm are formed. After that, the entire surface is coated by spin coating with a polymer material II, which has a composition slightly different from the polymer material I and has a refractive index lower than that of the polymer material I as shown in FIG. 2. By polishing the surface, the top surface of the cores 31 is exposed. The refractive index of the material in the core 31 is around 1.7 and that in the cladding is around 1.5.

In a manner similar to the conventional configuration shown in FIG. 14, the liquid crystal layer 33 is sandwiched by plastic substrates made of acrylic resin, styrene resin, polycarbonate, polyether sulfone, or the like, thereby forming the light extracting portion 33.

For the color filters with light diffusing function 34, 35, and 36, a polymer material used as a light diffusing material of an internal scattering member of a reflection type liquid crystal display (LCD) or a backlight is mixed into a color filter material. The electrode is formed by depositing a metal material such as Al or Cr or a transparent electrode material such as ITO or a material obtained by adding Sn, In, or the like to ITO on the whole surface by sputtering or the like and is patterned by photolithography.

An alignment layer is formed by coating a polyimide or a polyamic acid as a precursor of polyimide on the entire surface by spin coating or the like, and the resultant layer is heated and sintered on a hot plate or the like, and rubbed.

At the time of forming the liquid crystal layer 33, by using either a nematic liquid crystal material, a ferroelectric liquid crystal material, or an antiferroelectric liquid crystal material generally used for a TFT-LCD, the thickness of the liquid crystal layer can be set in a range from 2 to 5 μm by spacers generally used in a liquid crystal assembling process of the TFT-LCD. When the display area of the display is small, the thickness of the liquid crystal layer 33 may be fixed in a range similar to the above range only by the thickness of the liquid crystal sealing material without using the spacers.

The manufacturing method and dimensions of the display of the invention are not limited to the numerical values and the manufacturing method as described above, but known manufacturing methods can be applied. The numerical values within the range of achieving the effect of the invention are matters belonging to the present invention. Even if the numerical values and the like exceed the range, the range is simply a range of design matters.

As described above, a display apparatus of the first embodiment of the present invention comprising: a plurality of light guiding means 30; a light emitting means 10, an emitting light of which includes a first polarization component and a second polarization component which is different from the first polarization component, that emits the light so as to enter the plurality of light guiding means 30; a liquid crystal layer 33, provided on the plurality of light guiding means 30, for making the light from the plurality of light guiding means 30 leak to an outside; and a polarization recycling means 40, provided between the light emitting means 10 and the plurality of light guiding means 30, for converting the second polarization component into the first polarization component.

### MODIFICATION OF FIRST EMBODIMENT

In the above description, the color filters having the function of diffusing light are disposed over the cores of the light guiding means. It is also possible to use light guiding means having no color filters and dispose normal color filters between the light emitting means and the light guiding means.

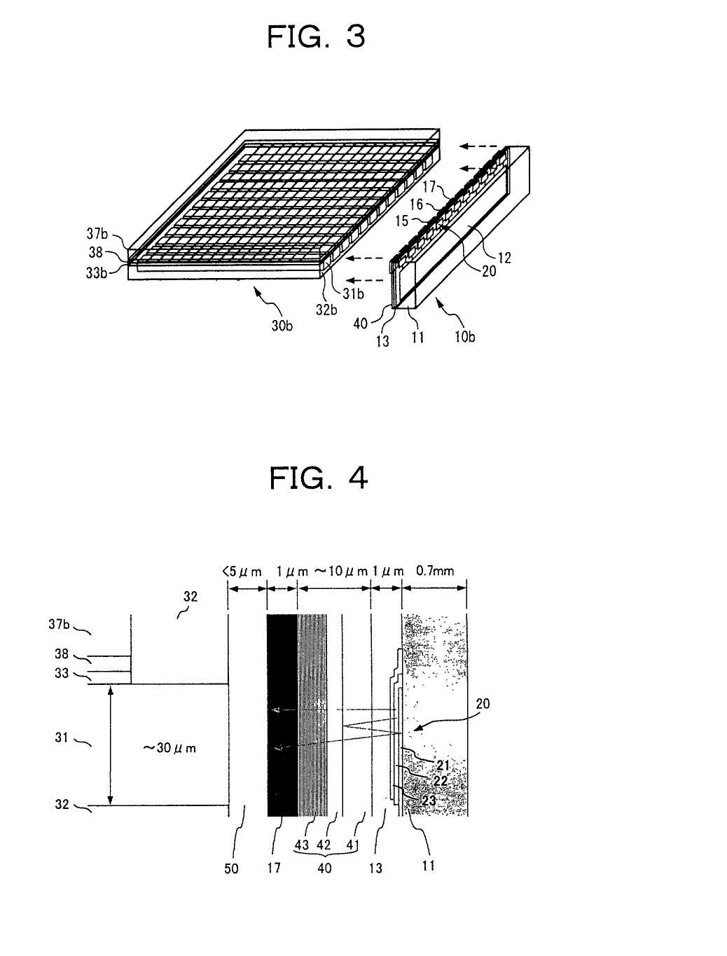

Such a configuration example is shown in FIGS. 3 and 4. FIG. 3 is an exploded perspective view showing components such as the light emitting means and the light guiding means. FIG. 4 is a cross section showing the details of the junction portion between them. This modification is different from the configuration as shown in FIGS. 1 and 2 with respect to only the position of disposing the color filters. Specifically, as shown in FIGS. 3 and 4, the color filters 15, 16, and 17 are closely attached to the top surface of the polarization recycling means 40 disposed on the top surface of the light emitting means 20. Light guiding means 30b needs a light scattering layer 38.

Although the example of the color display constructed by the white light emitting means and the color filters has been described in the modification, for example, blue light emitting means may be used in place of the white light emitting means and a color converting layer may be used in place of the color filters. In the case of using the color converting layer in place of the color filters, the wavelength of light emitted by the light emitting means is limited in a narrow range. Consequently, a layer having only one kind of a spiral pitch (for example, only a liquid crystal having a pitch corresponding to blue) may be used as the cholesteric liquid crystal layer polymer. The position of the layer for converting color from blue to green and the position of the layer for converting color from blue to red may be on the cores of the light guiding means or between the light emitting means and the light guiding means in a manner similar to the color filters.

As described above, in the modification, the components can be variously replaced without departing from the gist of the invention. Replacements of the components in a range without departing from the scope of the invention are also therefore included within the modification of the present invention.

### SECOND EMBODIMENT

A second problem of the conventional technique is that, when the angular distribution of the light emitting element is wide, the number of photons which cannot propagate through the light guiding means increases as the distance between the light emitting element and the end portion of the light guiding element becomes larger, and the efficiency for light utilization accordingly deteriorates. To solve such a problem, it is desired to use a light emitting element having a narrow angular distribution.

A second embodiment of the invention is carried out on the basis of this motivation.

The configuration and operation will be sequentially described hereinbelow.

As light emitting elements with a narrow angular distribution, an edge emitting type EL light emitting element and an organic EL light emitting element having therein a dielectric mirror are known. In this embodiment, by forming such elements in an array, a light emitting means can be constructed.

The organic EL light emitting element having therein a dielectric mirror emits light from its surface like a normal organic EL light emitting element. Therefore, in a manner similar to the configuration shown in FIG. 1 or 3 according to the first embodiment, we can mount such a light emitting element array together with the light guiding means.

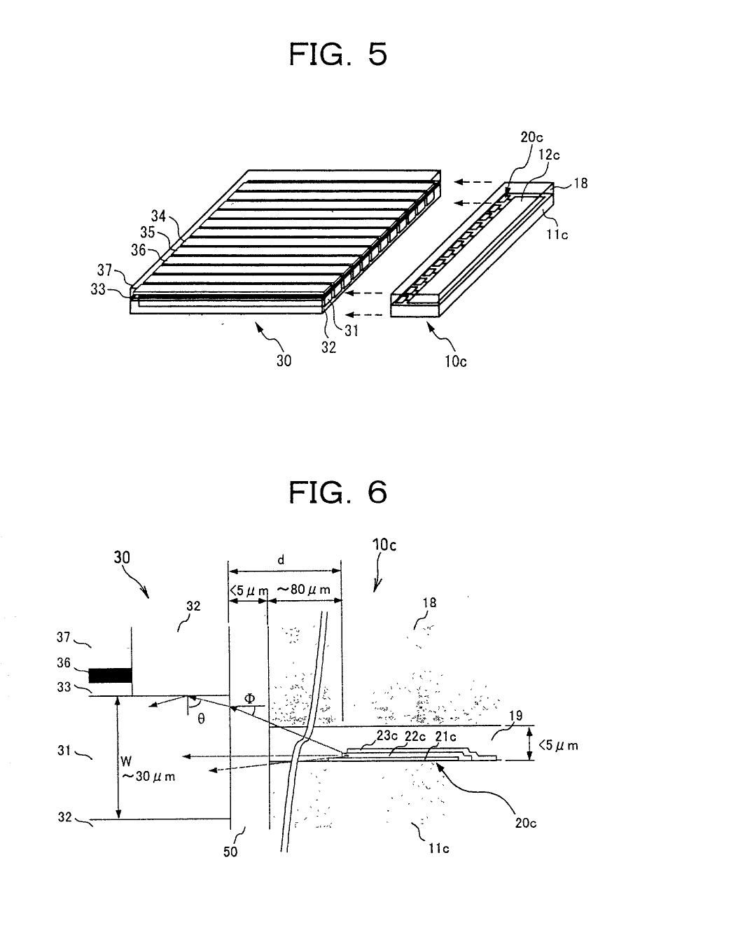

The edge emitting type EL element array emits light from its edge. In the case of using such an element as light emitting means, we can mount these components as shown in FIGS. 5 and 6.

In FIGS. 5 and 6, the same components as those in the first embodiment are designated by the same reference numerals. As shown in FIG. 5, light emitting means 10c is constructed by forming a plurality of light emitting elements 20c and a driving circuit 12c for driving the light emitting elements 20c on an insulating substrate 11c and fixing a supporting member 18 via an adhesive layer 19.

The light emitting element 20c is formed by, as shown in FIG. 6, sequentially stacking a bottom electrode 21c, an organic EL layer 22c, and a top electrode 23c. As the materials for the electrodes, reflecting metals such as Al containing Mg, Li, or the like are used.

In the embodiment, in a manner similar to the first embodiment, the organic EL layer can have a configuration such as the two-layered structure constructed by a hole transport material and a light emitting layer or a three-layered structure obtained by adding an electron transport layer to the two-layered structure.

The light guiding means 30 has the same configuration as that in the first embodiment. The light emitting means 10c and the light guiding means 30 are fixed by the adhesive layer 50.

In order to efficiently produce the edge emitting type organic EL light emitting element array, a process of forming a number of light emitting element arrays and the drive circuits on a large-area substrate and, after that, dicing the substrate has to be taken. However, since a limited cutting margin is necessary for dicing the substrate and, due to the existence of the cutting margin, the edge of the light emitting element and that of the substrate cannot be actually made coincide with each other. Therefore, the light emitting edge of the light emitting means cannot be closely attached to the cores of the light guiding means.

Let's denote the distance between the edge face of the light emitting element 20c and that of the cores as “d”, the height of the core as “w” and the minimum incident angle (which will be described hereinafter) to the interface with the liquid crystal layer for the light to propagate through the cores as θ. When the refractive indexes of all the adhesive layer 19, supporting member 18, insulating substrate 11c, and adhesive layer 50 are the same, the following expression is obtained. When the refractive indexes of the layers are different from each other, by applying the Snell formula to each of the interfaces, a similar expression can be obtained.

$$d < \frac{w}{2} tan θ \qquad ( Eq . 1 )$$

The operation of the embodiment will now be described.

Light emitted from the edge of the light emitting element 20c passes through the adhesive layer 19, supporting member 18 or insulating substrate 11c and the adhesive layer 50 and enters the core 31 in the light guiding means 30. Since it is assured from the expression (Eq. 1) that all of the light emitted from the edge of the light emitting element 20c propagates through the cores, there is no loss of light in the optical junction between the light emitting means 10c and the light guiding means 30. The operation after the light enters the core is similar to that in the first embodiment.

The minimum incident angle θ to the interface with the liquid crystal layer, with which the light can propagates inside the cores, is a very important design parameter since it determines the maximum distance between the core of the light guiding means 30 and the light emitting edge of the light emitting means 10c before light loss occurs, that is, the permissible cutting margin. To obtain this value, analysis described hereinafter is necessary. Specifically, a phenomenon that light propagating through the high refractive index area of the light guiding element enters the liquid crystal layer will be analyzed by mentioning concrete numerical values as an example.

The liquid crystal is regarded as a uniaxial crystal and its refractive indexes for ordinary light and extraordinary light are denoted as n₀ and nₑ, respectively. Depending on whether an external electric field is applied or not, two orientation states shown in FIG. 14 are considered. The angle formed between the normal direction of the liquid crystal layer and the light incident direction is denoted as θ.

With respect to a polarization component whose electric field vibrates in the direction parallel to the drawing sheet, the refractive index of the liquid crystal layer changes depending on the angle θ and is given by the following equation (Eq. 2) according to the orientation state.

In the case of vertical orientation:

$$n = \frac{{n}_{e} {n}_{o}}{\sqrt{{n}_{e}^{2} {cos}^{2} θ + {n}_{o}^{2} {sin}^{2} θ}} \qquad ( Eq . 2 )$$

In the case of horizontal orientation:

$$n = \frac{{n}_{e} {n}_{o}}{\sqrt{{n}_{e}^{2} {sin}^{2} θ + {n}_{o}^{2} {cos}^{2} θ}} \qquad ( Eq . 3 )$$

In order to propagate light through the light guiding element, the condition of total internal reflection has to be satisfied at the interface between the high refractive index area (having the refractive index=n_{core}) and the low refractive index area (having the refractive index=n_{clad}) of the light guiding element.

The condition is expressed as follows by using a critical angle θ_{c}.

Condition for the light not to be leaked to the low refractive index area: θ_{c}<θ

$${θ}_{c} = {sin}^{- 1} \frac{{n}_{c l a d}}{{n}_{c o r e}} \qquad ( Eq . 4 )$$

Similarly, whether the light reaching the liquid crystal layer undergoes total internal reflection or not is determined by the critical angle for total internal reflection. The critical angles θ_{c}^{v} and θ_{c}^{h} according to the orientation states are obtained by substituting n_{clad} in (Eq. 4) with expressions in (Eq. 2) and (Eq. 3). θ_{c}^{v} and θ_{c}^{h} indicate the vertical and horizontal components, respectively, in the orientation state of the critical angle θ_{c}.

Three kinds of the actual liquid crystals will now be assumed and the condition for extracting light to the outside of the light guiding element is considered.

Table 1 shows the data for the liquid crystals used hereinafter.

TABLE 1
Parameters of the liquid crystals studied here;

| Liquid crystal | nₑ | Nₒ | Δn |
|---|---|---|---|
| ZLI-45 | 1.6328 | 1.5026 | 0.1302 |
| ZLI-4619 | 1.5634 | 1.4811 | 0.0823 |
| ML-1007 | 1.7188 | 1.5138 | 0.205 |

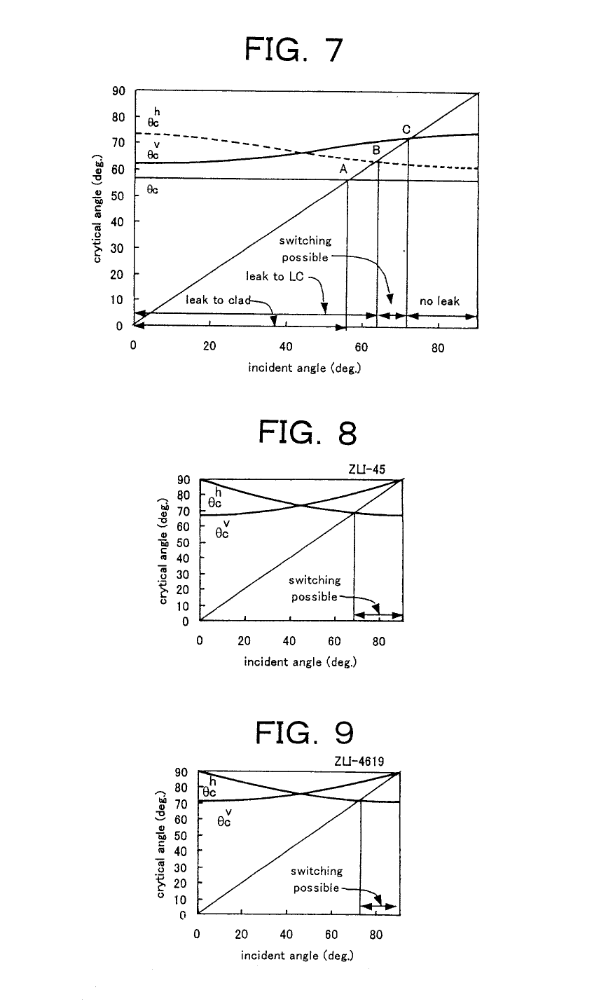

First, for the liquid crystal ZLI-45, n_{core} and n_{clad} were set to 1.70 and 1.50, respectively, and from the difference Δn (=n_{core}-n_{clad}) I three kinds of critical angles were calculated. The result is shown in FIG. 7 as a function of the incident angle θ.

θ_{c}^{v} and θ_{c}^{h} depend on the incident angle θ, and the following cases are considered according to the relation with θ.

(1) θ<θ_{c}: The light leaks to the low refractive index area.

(2) θ_{c}<θ<θ_{c}^{h}: The light does not leak to the low refractive index area but leaks to the liquid crystal layer.

(3) θ_{c}^{h}<θ<θ_{c}^{v}: According to the orientation, the horizontal orientation (h of θ_{c}^{h} means horizontal) or the vertical orientation (v of θ_{c}^{v} means vertical), leakage of light to the liquid crystal layer can be controlled.

(4) θ_{c}^{v}<θ: The light is confined in the high refractive index area.

To increase the amount of light which can be controlled, it is desirable angle range of θ_{c}^{h}<θ<θ_{c}^{v} to be wider. That is, the point A in FIG. 7 has to be on the left side of the point B, and the point C has to be close to θ=90° as much as possible.

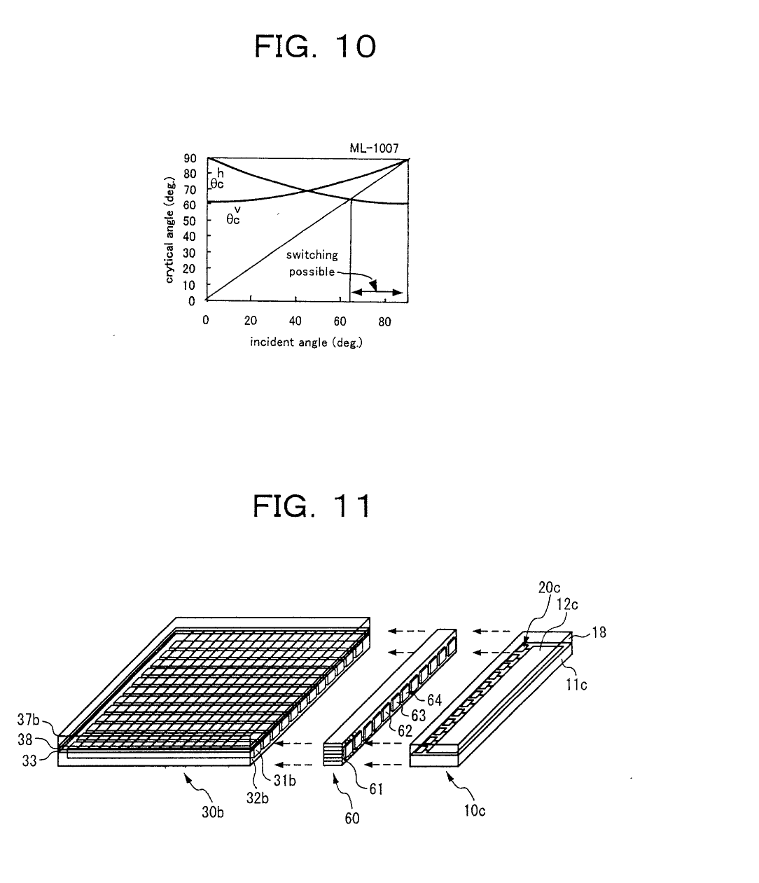

When n_{core} is set to nₑ of the liquid crystal, the point C can be made coincide with θ=90°. FIGS. 8 to 10 show results of calculation for critical angles θ_{c}^{v} and θ_{c}^{h} when n_{core} is set to nₑ.

As shown in FIGS. 8 to 10, the range for the incident angle θ of light in which leakage from the liquid crystal layer to the outside can be controlled is 69°<θ<90° (in the case of the liquid crystal ZLI-45), 73°<θ<90° (in the case of the liquid crystal ZLI-4619), and 65°<θ<90° (in the case of the liquid crystal ML-1007). Therefore, it is understood that, among the three kinds of liquid crystals, light can be most efficiently used in the case of the liquid crystal ML-1007. In this case, when the refractive index of the adhesive layer 50 is 1.5, the incident angle φ of light from a light source to the core (refer to FIG. 6) lies in the range of −29°<φ<29°. Therefore, if a light source having directivity narrower than this angle range is used, all the light emitted can be used.

Directivity of the edge emitting type organic EL light emitting element is described by, for example, M. Hiramoto et al., “Directed beam emission from film edge in organic electroluminescent diode” (Appl. Phys. Lett. Vol. 62, No. 7, pp. 666-668, 1993). In this example, all the light is emitted in the angle range of ±10°.

In the light guiding means having numerical values used for the analysis in the example of the present invention, the directivity of light emitted from the edge emitting type organic EL element is sufficiently narrower than the incident angle range required for light propagation through the core. Consequently, if only when the light reaches the core, in principle, all the emitted light can be used for display purpose.

In the above example of analysis, to make the light reach the core geometrically, when w=30, d<30/2×tan(90×10)=85 μm by using the equation (Eq. 1). This value for “d” is readily accepted for a margin for cutting the substrate when the light emitting element arrays are mass-produced. That is, the edge emitting type element which can be easily mass-produced can be mounted on the light guiding means. The display constructed in such a manner can utilize most of the light emitted by the light emitting elements.

An output of the edge emitting type organic EL light emitting element is described by, for example, A. Fujii et al., “Anisotropic optical properties of an organic electroluminescent diode with a periodic multilayer structure” (Thin Solid Films 273, pp. 199-201, 1996).

As described in the literature, in the case in which the organic material layer has the simple two-layered structure constructed by the hole transport layer and the light emitting layer, it is known that the polarization components having the electric field which vibrates parallel to the stack direction become almost 100%. Therefore, the polarization recycling means used in the first embodiment may not be used in the case in which the edge emitting type element is used as described in this embodiment.

### MODIFICATION OF THE SECOND EMBODIMENT

In a modification of the second embodiment, in a manner similar to the modification of the first embodiment, without departing from the gist of the invention, the components can be variously replaced.

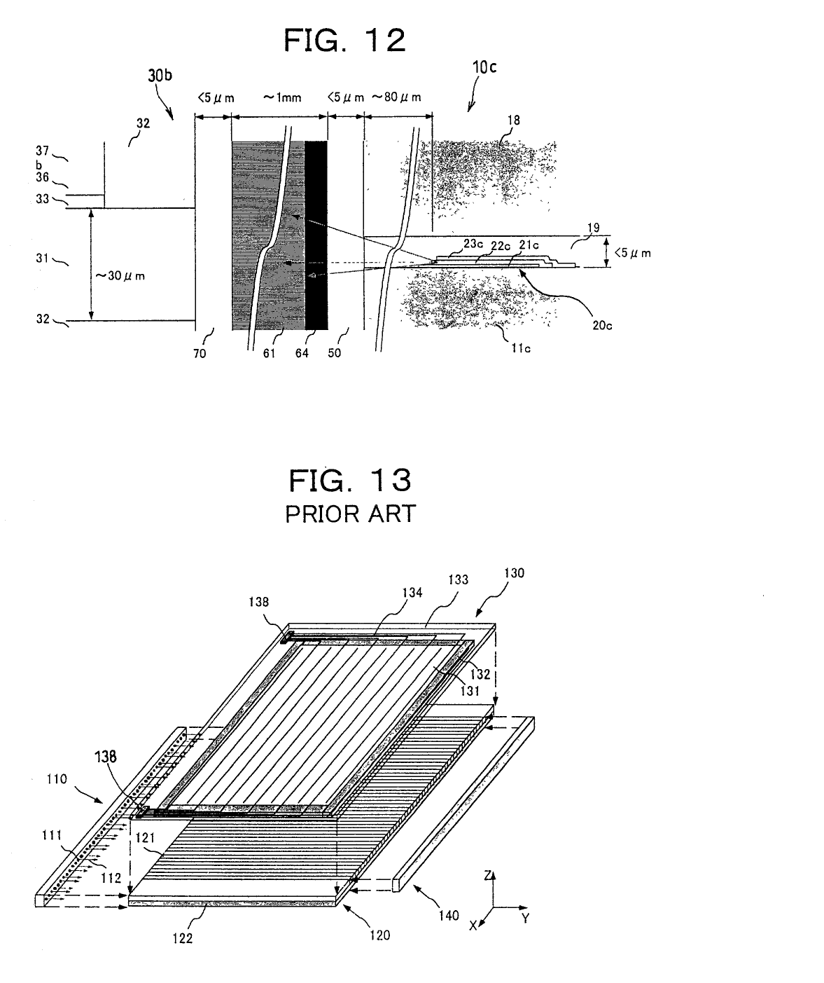

For example, in the above description, the color filters having the function of diffusing light are disposed over the cores of the light guiding means. However, conventional color filters may be disposed between the light guiding means and the light emitting means. An example of such a configuration is shown in FIGS. 11 and 12. FIG. 11 is an exploded perspective view showing components such as light emitting means and the light guiding means. FIG. 12 is a cross section showing the details of the joint portion of both of the means.

This modification is different from the second embodiment shown in FIGS. 5 and 6 with respect to a point that optical means 60 for disposing the color filters is used and a point that the light scattering layer 38 is provided instead of using the color filters for the light guiding means 30b.

As shown in FIG. 11, the optical means 60 is constructed by closely attaching color filters 62, 63, and 64 on the surface of an optical fiber bundling member 61. In the case where color filters are directly formed at the edge of the light emitting means 10c, the optical means 60 can be made unnecessary.

The optical fiber bundling member is an optical component having a thickness of about 1 mm constructed by bundling a number of optical fibers. It guides incident light to the other surface through each of the optical fibers. Consequently, the light is not spread during propagation 10 through this component. Since the thickness is about 1 mm, handling at the time of assembly is also easy. As shown in FIG. 12, the optical means 60 is fixed to the light emitting means 10c and the light guiding means 30b by adhesive layers 50 and 70, respectively. The light guiding means 30b has the same configuration as that of FIG. 3.

Although the color filters 64 of the optical means 60 face the light emitting means 10c in FIG. 12, the color filters 64 may be disposed on the other side of the component 61 to face the light guiding means 30b.

In a manner similar to the first embodiment, blue light emitting means may be used in place of the white light source, and a color converting layer may be used in place of the color filter.

Although the invention has been illustrated and described with respect to exemplary embodiment thereof, it should be understood by those skilled in the art that the foregoing and various other changes, omissions and additions may be made therein and thereto, without departing from the spirit and scope of the present invention. Therefore, the present invention should not be understood as limited to the specific embodiment set out above but to include all possible embodiments which can be embodies within a scope encompassed and equivalents thereof with respect to the feature set out in the appended claims.

Effects of the invention will be described on the basis of the embodiments.

In the first embodiment, a polarization component which is conventionally lost can be recycled and the efficiency for light utilization is almost doubled. Consequently, brightness twice as high as the conventional one can be obtained. Alternatively, the power consumption of the light emitting means can be reduce to about one half of the conventional one. It is therefore advantageous to apply the present invention to a device such as a portable information terminal or a notebook-sized PC, in which low power consumption is important. By employing the configuration of disposing color filters having the function of diffusing light over the cores of the light guiding means, the manufacturing process of forming the conventional light scattering layer can be made unnecessary, and thereby the manufacturing cost can be reduced.

In the second embodiment, as a result of analyzing the operation of the display in detail, the edge emitting type element, which can be readily mass-produced, can be mounted on the light guiding means. Consequently, most of light emitted by the light emitting elements can be effectively used for display. With the configuration including the optical fiber bundling member in which color filters are formed, assembling is made easy.

What is claimed is:

1. A display apparatus comprising:
a plurality of light guiding means;
a light emitting means, an emitting light of which includes a first polarization component and a second polarization component which is different from said first polarization component, that emits light so as to enter said plurality of light guiding means;
a liquid crystal layer, provided on said plurality of light guiding means, for making said light from said plurality of light guiding means leak to an outside; and
a polarization converting means, provided between said light emitting means and said plurality of light guiding means, for converting said second polarization component into said first polarization component.

2. The display apparatus according to claim 1, wherein said polarization converting means is formed by stacking a cholesteric liquid crystal polymer, a quarter-wave plate and a linear polarization plate.

3. The display apparatus according to claim 1, wherein said light emitting means comprising a bottom electrode made of a reflecting material formed on a substrate and a top electrode made of a transparent material and an organic electroluminescence layer provided between said bottom electrode and said top electrode.

4. The display apparatus according to claim 1, wherein said light emitting means is an edge emitting type light emitting element.

5. The display apparatus according to claims 1, wherein said light emitting means outputs white light and color filters are disposed over said liquid crystal layer.

6. The display apparatus according to claim 1, wherein said color filter includes a component for scattering a light that is extracted via said liquid crystal layer.

7. The display apparatus according to claims 1, wherein said light emitting means outputs white light and color filters are disposed between said light emitting means and said plurality of light guiding means.
